(19) United States
(12) Patent Application Publication
(10) Pub. No.: US 2004/0128095 A1
(43) Pub. Date: Jul. 1, 2004

(54) Adaptation of the timing advance in synchronous handover

(76) Inventor: Stefan Oestreich, Holzkirchen (DE)

Correspondence Address: STAAS & HALSEY LLP, SUITE 700, 1201 NEW YORK AVENUE, N.W., WASHINGTON, DC, 20005, US

(21) Appl. No.: 10/344,675

(22) PCT Filed: Aug. 10, 2001
(86) PCT No.: PCT/DE01/03079

(30) Foreign Application Priority Data
Aug. 16, 2000 (DE) 100 39 967.3

(51) Int. Cl. G01D 18/00; G01M 19/00; G06F 19/00; G01D 21/00; G01P 21/00; G01R 35/00

(52) U.S. Cl. 702/89

(57) ABSTRACT

To adapt the timing advance of a mobile terminal during synchronous handover from a first to a second base station of a radio communications system, a time delay between time standard received by the terminal from the two base stations is measured. A timing advance value that is used by the terminal prior to handover for transmission to the first base station is corrected using the measured time delay. The corrected timing advance value is reduced by a value derived from the accuracy of the synchronicity of the two base station and is used as the timing advance value for transmission to the second base station.

The present invention relates to a method for adapting the timing advance of a mobile terminal during synchronous handover between two base stations of a radio communication system and to a radio communication system in which such a method can be used.

For communication with a base station in radio communication systems with time division multiplex, each terminal is allocated a time slot, i.e. a periodically repeated time interval in which it is allowed to send data to the base station. The length of these time slots is so short that, by comparison, the time required by a radio signal for traveling the distance from the terminal to the base station is not negligible. To ensure that radio signals of a terminal actually arrive at the base station in the time slot allocated to the terminal, the base station regularly estimates the signal delay for each terminal and transmits to the terminal a so-called timing advance value derived from this measurement, which tells the terminal by how much time it must advance its signal compared with a timing standard radiated by the base station, in order to ensure that the signal arrives at the base station in the timing window intended for it.

Since the radio signals between the terminals and the base station frequently propagate simultaneously over a number of paths which can have different lengths and thus different signal delays, the time slots allocated to different terminals are in each case separated by a so-called guard period. Within this guard period, signals of a terminal which have a longer propagation path than the dominant propagation path for which the timing advance of the terminal is dimensioned can also reach the base station without overlapping the signals of other terminals. Thus, these signal components can be used at the base station additionally to the dominant signal component in order to improve the quality of the symbol estimation.

If, however, the signal of a terminal which is allocated the time slot following the guard period arrives too early and partially overlaps the guard period, the base station is not able to correctly detect the position of the signal in its receiving window. In such a case, the base station is not able to allocate the signal to a call or transmission session. The signal is lost.

In second-generation mobile radio communication systems such as the GSM system, the timing standards of adjacent cells are not synchronized, as a rule. This means that in the case of a handover of a terminal from a first cell to a second one, the timing advance of the terminal must be measured again completely for the second cell before a current communication with the terminal is correctly synchronized to the receiving window in the second cell. In the meantime, the subscriber station must transmit with a timing advance value of 0, if necessary. Although this eliminates the possibility that the signal arrives too early at the base station, the delay accepted in turn, which is proportional to the distance of the terminal from the base station, can be considerable.

More recent radio communication systems such as UTRA, TDD provide for a synchronization of adjacent cells, i.e. the timing standard or the radio frames, respectively, are radiated at the same time in both cells. A terminal which is about to carry out a handover between two synchronized cells, a so-called synchronous handover, therefore, receives the timing standards of the two base stations between which the handover is taking place, in each case with a delay which corresponds to its distance from the two base stations. In the ideal case where both base stations are perfectly synchronized, the terminal can thus directly derive the timing advance value applicable to the new base station by measuring the relative timing offset between the two timing standards at its location, knowing the timing advance value applicable to its old base station. Thus, the terminal can immediately transmit to the new base station with the correct timing advance without first having to wait for a timing advance measurement by the new base station and the transmission of the result of the measurement.

It is obvious that a synchronization of the timing standards of second base stations can scarcely ever be completely free of errors. If an error in synchronism leads to the terminal calculating too large a value of the timing advance for the new base station and correspondingly transmitting too early, this will lead to a part of its signal still arriving at the new base station during the guard period of a preceding time slot and thus being lost. Since sign and amount of the synchronism error are not known, the terminal is not able to take it into consideration in the resetting of its timing advance value in order to thus synchronize its signal at the new base station with the timing window allocated to it.

It is the object of the present invention to specify a method for adapting the timing advance of a mobile terminal during the synchronous handover from a first base station to a second base station of a radio communication system, in which remeasuring of the timing advance value by the second base station can be largely avoided and in which, nevertheless, no data losses occur due to an errorred determination of the timing advance value by the terminal.

The invention is based on the finding that, although the actual synchronism error between two base stations cannot be specified in the individual case of a specific handover, it is possible, as a rule, to specify the accuracy of the synchronism of the two base stations, i.e. to estimate an upper limit for the amount of the synchronism error which it will not exceed with a predetermined probability.

Reducing the timing advance value determined by the terminal by means of a time shift between the timing standards of the two base stations, that is to say delaying the transmission by the subscriber station, in dependence on the known accuracy of the synchronism, has the result that the radio signal of the terminal radiated with reduced timing advance may not arrive at the second base station immediately at the beginning of the allocated time slot but in no case before the beginning of the time slot. On the other hand, it is possible to tolerate the radio signal reaching into the guard period following the time slot.

The reduction in the timing advance value is preferably twice the accuracy of the synchronism specified in units of time.

If the accuracy of the synchronism is too poor, a reduction of the timing advance value corrected by means of the measured time shift could lead to significant parts of the radio signal falling into the guard period or even into the subsequent time slot of another station at the base station. In such a case, it is more appropriate to completely dispense with a correction of the timing advance value and to use a timing advance value of 0 for transmitting to the second base station. In this case, remeasuring of the timing advance by the second base station is unavoidable.

The accuracy of the synchronism of the two base stations involved in the handover is preferably signaled to the terminal during the handover process. This allows the network operator to calculate or to measure the accuracy of the synchronism in the individual case for each pair of base stations which can be involved in a handover and to provide an accuracy value thus obtained to all terminals which must perform a handover between said two base stations.

As an alternative, heuristic estimations of the accuracy of the synchronism are also conceivable. Thus, it can be assumed, for example, that the accuracy of the synchronism is proportional to the distance between two base stations. The distance to the first base station is known to the terminal from its timing advance used before the handover. Assuming that the distance to the second base station will be of a similar order of magnitude to that to the first one, the terminal can derive an estimated value for the accuracy of the synchronism directly from the timing advance value.

It is appropriate for technical handling if the pairs of base stations of the radio communication system are graded into one of a number of classes depending on the accuracy of their synchronism and in each case the class to which the pair of stations between which the handover is taking place is signaled to the terminal. Thus, the signaling of the accuracy of the synchronism can be limited to the transmission of a small number of bits. If the terminal assumes the upper limit of such a class as the value for the accuracy of the synchronism, a premature arrival of the signal at the base station is reliably avoided independently of the actual value of the accuracy.

The number of classes is preferably at least three. These classes include preferably one where the accuracy of the synchronism is so good that a reduction of the timing advance value corrected by means of the measured time shift can be completely dispensed with. Such a class suitably comprises pairs of stations in which the accuracy of the synchronism does not exceed a limit value within the range of 100-500 ns.

A further class subdivision suitably delimits those pairs of stations where a reduction in the timing advance value by a value derived from the accuracy of the synchronism is appropriate, with respect to the pairs where the accuracy of the synchronism is so poor that a complete redetermination of the timing advance by the second base station is more advantageous. The limit value for this subdivisicn is suitably within a range of between 500 ns and 2.5 μs.

Further features and advantages of the invention are obtained from the subsequent description of an exemplary embodiment, referring to the attached figures, in which:

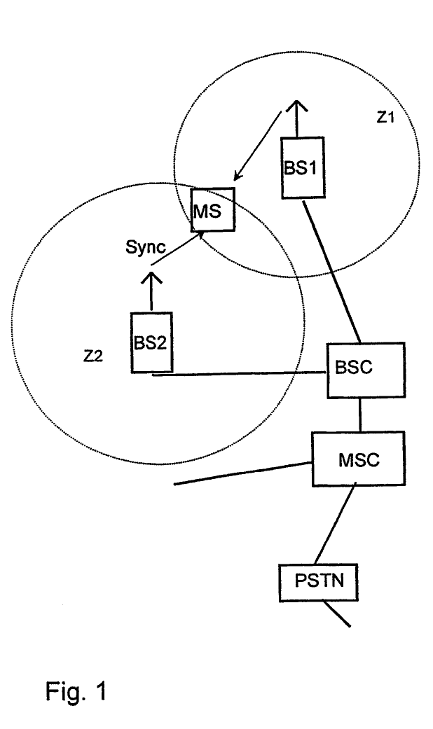

FIG. 1 shows a block diagram of a radio communication system in which the present invention can be used;

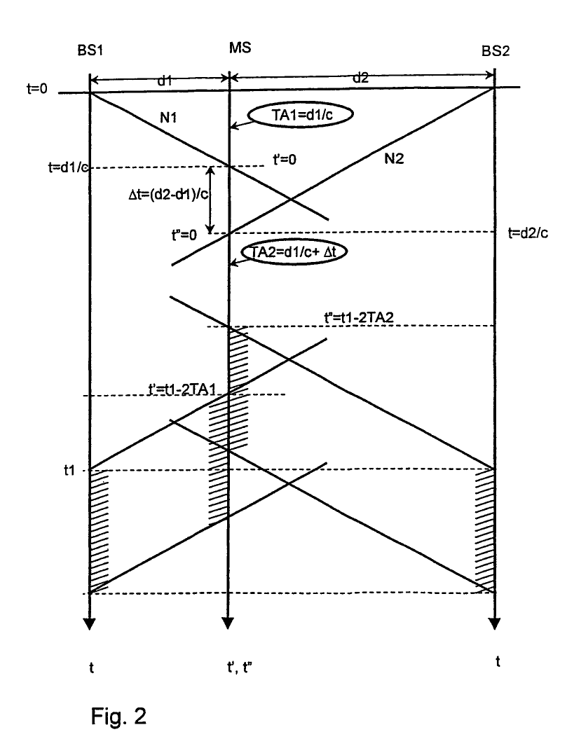

FIG. 2 shows a timing diagram for explaining the determination of the timing advance value by a terminal in the case of a handover;

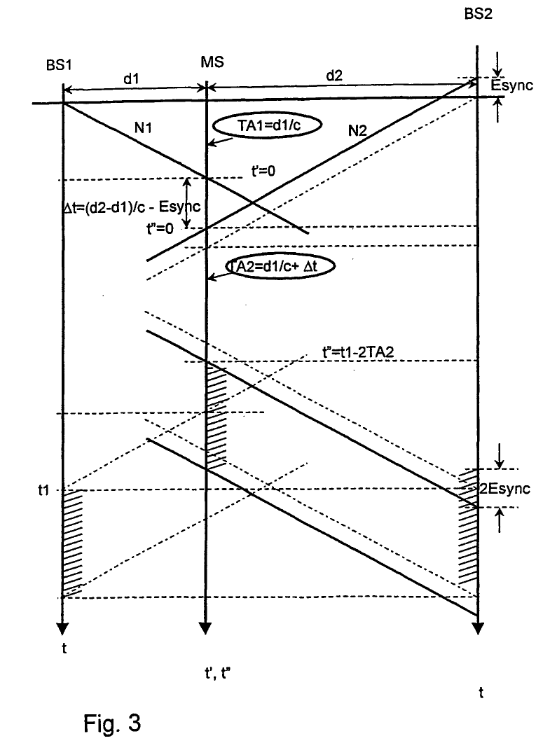

FIGS. 3+4 show the effects of synchronism errors on the determination of the timing advance value;

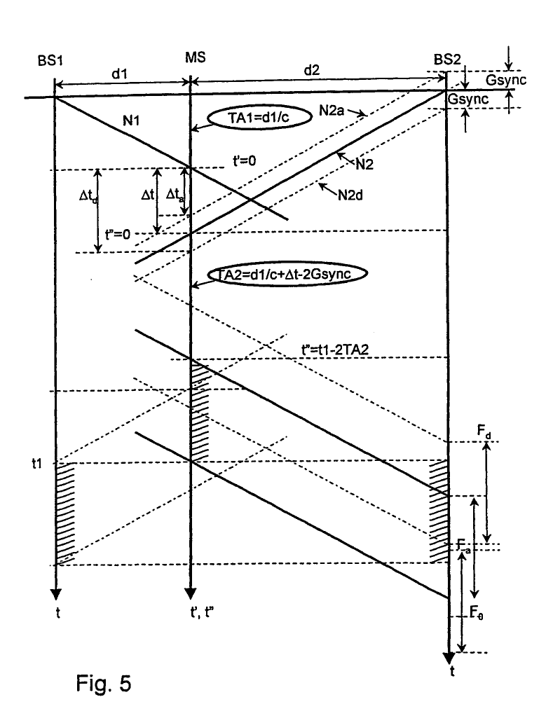

FIG. 5 shows how the accuracy of the synchronism is taken into consideration during the determination of a timing advance value by the terminal.

FIG. 1 shows the structure of a radio communication system in which the method according to the invention can be used. It comprises a multiplicity of mobile switching centers MSC which are networked together or establish access to a landline network PSTN, respectively. Furthermore, these mobile switching centers MSC are connected to in each case at least one base station controller BSC. Each base station controller BSC, in turn, provides for a connection to at least one base station, in this case base stations BS1, BS2. Each such base station can set up a communication link via an air interface to terminals such as the terminal MS which is located in the corresponding cell Z1 or Z2, respectively.

In this text and in the text following, the terminology familiar from the GSM system is used for designating the functional units of the radio communication system. The problem solved by the present invention, however, is common to all time division multiplex radio communication systems in which the base stations of adjacent cells are synchronized to one another. Thus, the term “base station” as used in the text which follows must in no way be understood as a restriction to GSM and related systems but also includes radio stations of any other time division multiplex radio communication systems.

FIG. 2 illustrates the adaptation of the timing advance of a terminal MS during a handover from a first base station BS1 to a second base station BS2 in the ideal case of perfect synchronization of the two base stations. In FIG. 2, each base station and the terminal are represented by timing axes, as errors at which events occurring in them are represented ordered in time. Perfect synchronization here means that the two base stations BS1, BS2 send out a timing standard such as the beginning of a frame at precisely the same time which is symbolized in the figure by two straight lines N1, N2 which in each case emanate from the base station BS1 and BS2, respectively, at time t=0. The timing standard N1 reaches the terminal MS at time t=d1/c where d1 is the path length between the base station BS1 and the terminal MS. This delay d1/c is also the value of the timing advance TA1 used by the terminal MS for transmission to the base station BS1.

For controlling the timing of its tasks before the handover, the subscriber station MS uses a local timing scale which is derived from the timing standard transmitted by the base station BS1. The time of the arrival of the timing standard N1 at the subscriber station MS can be defined as the zero point t′=0 of its timing scale t′ referred to the base station BS1.

The terminal MS is allocated a time interval for transmission to the base station BS1 which begins at a time t=t1 and is symbolized by a shaded section along the timing axis of the base station BS1. So that the signal radiated by the terminal MS reaches the base station BS1 within this timing window, it must already begin to transmit at a time t=t1−TA1. Since the local timing scale of the terminal lags that of the base station BS1 by TA1, this corresponds to time t′=t1−2×TA1 on the timing scale t′ of the terminal.

The timing standard N2 of the base station BS2 arrives at the terminal MS later than the timing standard N1 by Δt=(d2−d1)/c, where d2 is the distance between the base station BS2 and the terminal MS. The arrival of the timing standard N2 defines a new zero point t1″=0 for the local timing scale of the terminal MS, starting from which the time for transmission to the base station BS2 is now specified.

The interval Δt between the arrival times of the two timing standards provides the amount by which the terminal MS must correct its timing advance value in order to be able to correctly communicate with the base station BS: the terminal MS specifies TA2=(d1/c)+Δt as the new timing advance value. It begins to send a burst to the base station BS2 from t″=t1−2×TA2. The burst arrives at the base station BS2 at the desired time starting from t=t1.

FIG. 3 shows the case of a synchronization error between the base stations BS1 and BS2: the base station BS2 transmits its timing standard earlier than the base station BS1 by Esync. The consequence is that the difference between the arrival times of the two timing standards N1, N2 measured by the terminal MS does not specify the actual difference of the delays from the base stations to the terminal but is too low by Esync. The new value TA2 of the timing advance, calculated by the terminal MS using this different Δt, is too small by Esync. The starting point t″=0 of the timing scale of the terminal referred to BS2 is earlier by Esync than in the case of FIG. 2; the transmission time t″=t1−2×TA2 calculated by the terminal MS is later by Esync. The receiving window of the base station BS2 for the signal of the terminal, symbolized by shading along the timing axis of the base station BS2 is earlier by Esync than that of the base station BS1. The signal of the terminal MS, therefore, arrives with a delay of 2×Esync at the base station BS2. However, this delay does not prevent the signal from being evaluated by the base station BS2 if the base station BS2 is still able to identify the midamble in the received burst and to align the estimation of the symbols of the received burst in time with this midamble.

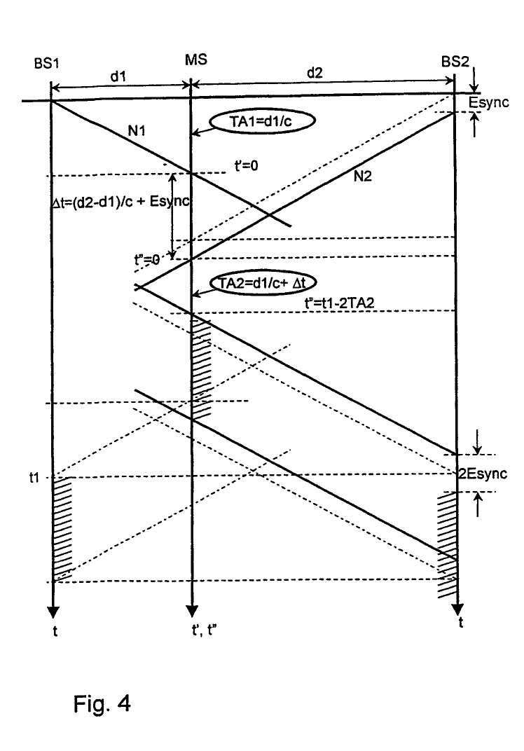

FIG. 4 shows the opposite case to FIG. 3. It is assumed that the base station BS2 transmits its frame with a delay Esync compared with the base station BS1. The terminal MS, therefore, measures too large a time difference Δt between the times of arrival of the timing standards. A value of the timing advance TA2 calculated from this time difference Δt is, therefore, too large, with the consequence that the terminal MS begins to transmit too early. Its signal, therefore, begins to arrive at the base station BS2 with a time shift of 2×Esync before the beginning of the timing window allocated to it and symbolized by shading along the timing axis of the base station BS2. In this case, the base station is no longer able to correctly identify the midamble so that it cannot correlate the received signal with the terminal MS. It may even happen that the base station BS2 wrongly allocates the signal to another terminal which is allocated a preceding receiving time slot, with the consequence that not only is the reception of the terminal MS performing the handover disturbed but also that of another uninvolved terminal. Such a situation must therefore be avoided under all circumstances.

FIG. 5 is used for describing how this risk is avoided by the method according to the invention. Firstly, an accuracy Gsync of the synchronism is determined for the pair BS1, BS2 of base stations, i.e. a limit value which must not be exceeded by the amount of the synchronism error Esync with a predetermined probability of e.g. 95% at a given time. This accuracy of the synchronism Gsync can be determined by measurements or possibly also calculated, knowing the means used for synchronization of the two base stations and their precision. This determination can be made at any time before the actual handover and is not shown in FIG. 5, therefore.

The accuracy of the synchronism Gsync is signaled to the terminal MS which is about to carry out a handover from base station BS1 to base station BS2, by one of the two base stations. As already described with reference to FIG. 2, the terminal MS then measures the difference Δt between the arrival times of the timing standards N1, N2 of the two base stations. From this, it calculates a new timing advance value TA2 for the communication with the second base station BS2 in accordance with the formula

In the case where the two base stations BS1, BS2 are perfectly synchronized, this results in the signal of the terminal MS arriving at the base station BS2 in a time interval F₀ which is delayed by 2×Gsync with respect to the receiving timing window shown shaded.

Assuming that the base station BS2 transmits too early by Gsync in comparison with the base station BS1, which corresponds to the dot-dashed timing standard line N2a in the figure, the terminal MS measures a time difference

Δtₐ=((d2−d1)/c)−Gsync;

resulting in a timing advance value

TA2ₐ=TA1+Δtₐ−2Gsync=TA1+((d2−d1)/c)−3Gsync.

Thus, the timing advance value is smaller by 3Gsync than in the case of FIG. 2; at the same time, the receiving window for the signal of the terminal MS is too early by Gsync at the base station BS2 so that the signal of the terminal MS arrives delayed by a total of 4Gsync with respect to its receiving window in the time interval Fₐ at the base station BS2.

If, in contrast, it is assumed that the base station BS2 has a delay of Gsync compared with the base station BS1 which corresponds to the dot-dashed timing standard line N2d in FIG. 5, this results in a difference between the timing standards of

Δtₐ=((d2−d1)/c)+Gsync.

The timing advance value is thus calculated as

TA2ₐ=TA1+Δtₐ−2Gsync=TA1(d2−d1)/c)−Gsync.

The timing advance value is thus smaller by Gsync than in the case of perfect synchronism. On the other hand, the receiving window of the base station BS2 is also delayed by Gsync compared with that of the base station BS1 so that the signal of the terminal MS exactly coincides with the receiving window F_{d} allocated to it at the base station BS2.

The risk that the signal of the terminal MS arrives too early at the base station BS2 to be evaluated correctly is thus eliminated independently of the amount and direction of the actual synchronism error Esync.

If the synchronization of the base stations BS1, BS2 is poor, that is to say Gsync assumes large values of e.g. 2.5 μs, the use of the method described above can lead to quite considerable reductions in the timing advance value and could even result in the timing advance value becoming negative. Such a value would correspond to a negative distance between the terminal MS and the second base station BS2, which is obviously physical nonsense. If the calculation described above supplies a value of TA2<0, therefore, TA2=0 is always set. To avoid excessive reductions in the timing advance value, it is also appropriate to define an upper limit value for the accuracy or the synchronism and to restrict the application of the method described above only to those pairs of base stations within a radio communication system whose synchronism is better than this limit value. During handover between base stations in which the synchronism is poorer than this limit value, the terminal MS uses a timing advance value of TA2=0 for the communication with the second base station until the base station BS2 transmits a command for setting a value measured by it.

According to a preferred embodiment of the method, it is not necessarily the accuracy of the synchronism which has been determined for the two base stations which is signaled to the terminal during handover between two base stations but only an information about the association of the relevant pair of base stations with one of several classes of accuracy which is transmitted. This reduces the number of bits required for signaling the accuracy to log 2 of the number of classes. In practice, four or even only three classes are sufficient: a first class to which tightly coupled pairs of stations with an accuracy of synchronism of typically approx. ±100 ns belong. During handover between two such stations, the consideration of the accuracy Gsync described above can lead to a delay of the signal by 400 ns in the worst case during the determination of the new timing advance value TA2, which is less than the duration of two chips (1 chip=approx. 250 ns), e.g. in a UMTS radio communication system with a spreading factor of 16. During the handover between pairs of base stations belonging to this class of accuracy, the accuracy of the synchronism can be completely ignored during the determination of the new timing advance value since any resultant displacements in time cannot impair the detection of the middle and thus the symbol estimation at the base station BS2.

A second class comprises pairs of base stations with a mean accuracy of the synchronism Gsync of typically ±500 ns. With such a value of Gsync, this consideration in the determination of TA2 can lead to an arrival of the signal delayed by 2 μs at the base, station BS2 in the worst case.

A third class of accuracy contains those pairs of base stations, already discussed above, in which the accuracy of the synchronism is so poor that their consideration in the determination of TA2 can lead to inappropriately large delays of the signal at the base station BS2.

When the association of the base stations BS1 and BS2 with the second class has been signaled to the terminal MS, it uses the upper accuracy limit value of this class as a basis for determining TA2 as Gsync.

When three classes are used, for example, all pairs of base stations with Gsync<200 ns can be graded in the first class, those with 200 ns<Gsync≦1 μs can be graded in the second class and all those with Gsync>1 μs can be graded in the third class. To keep the signal delays obtained by taking into consideration Gsync as small as possible in the individual case, it may be desirable to subdivide the second class more finely. Thus, e.g. a subdivision is also conceivable where a class 2a contains all pairs of stations with 200 ns<Gsync≦500 ns and a class 2b contains the pairs with 500 ns<Gsync≦1.5 μs. In such a case, the terminal MS would use as a basis for determining TA2 an accuracy of =500 ns during handover between stations of class 2a, an accuracy Gsync=1.5 μs in the case of stations of class 2b.

1. A method for adapting the timing advance (TA1, TA2) of a mobile terminal (MS) during synchronous handover from a first base station to a second base station (BS1; BS2) of a radio communication system, in which a time displacement (Δt) is measured between timing standards (N1, N2, N2a, N2d) which are received by the terminal (MS) from the two base stations (BS1, BS2), and a timing advance value (TA1) used by the terminal (MS) before the handover for transmission to the first base station (BS1) is corrected by means of the measured time displacement (Δt, Δtₐ, Δt_{d}), characterized in that the corrected timing advance value is reduced by a value derived from the accuracy (Gsync) of the synchronism of the two base stations (BS1, BS2) and used as timing advance value (TA2) for transmission to the second base station (BS2).

2. The method as claimed in claim 1, characterized in that the derived value is twice the accuracy (Gsync) of the synchronism, specified in units of time.

3. The method as claimed in one of the preceding claims, characterized in that, if the accuracy (Gsync) of the synchronism exceeds a predetermined limit value, the timing advance value (TA2) used for the transmission to the second base station is set to zero.

4. The method as claimed in one of the preceding claims, characterized in that the accuracy (Gsync) of the synchronism is signaled to the terminal (MS).

5. The method as claimed in claim 4, characterized in that the pair of the two base stations (BS1, BS2) is graded into one of a number of classes depending on the accuracy of their synchronism and that the class to which the pair belongs is signaled to the terminal (MS).

6. The method as claimed in claim 5, characterized in that the number of classes is at least three.

7. The method as claimed in claim 5 or 6, characterized in that a first limit value of the accuracy which separates a first class and a second class from one another is between 100 and 500 ns and that, if the accuracy of the synchronism is better than the first limit value, the value derived from the accuracy of the synchronism is set equal to zero.

8. The method as claimed in one of claims 5 to 7, characterized in that a second limit value of the accuracy which separates a second class from a third class is between 500 ns and 2.5 μs and that, if the accuracy of the synchronism falls into the second class below the second limit value, the value derived from the accuracy of the synchronism is set equal to twice the second limit value.

9. A radio communication system comprising a plurality of cells (Z1, Z2) synchronized with one another with a known accuracy, characterized in that during a handover of a terminal (MS) between two of its cells (Z1, Z2), it signals an information about the synchronism of these two cells (Z1, Z2) to the terminal (MS).
